(19) United States
(12) Patent Application Publication
(10) Pub. No.: US 2009/0097212 A1
(43) Pub. Date: Apr. 16, 2009

(54) Optimization of connector density and identification carrier for high density front plates

(76) Inventors: Bevin Schmidt, Dunrobin (CA); Fabien Letourneau, Gatineau (CA)

Correspondence Address: KRAMER & AMADO, P.C., 1725 DUKE STREET, SUITE 240, ALEXANDRIA, VA, 22314, US

(21) Appl. No.: 11/907,557

(22) Filed: Oct. 15, 2007

(51) Int. Cl. H05K 1/00; H01R 12/14

(52) U.S. Cl. 361/748; 439/59

(57) ABSTRACT

A high connector density printed circuit board, and high connector density device containing the same, including one or more of the following: a face plate; a plurality of connector ports in the face plate; a tab integral with the face plate label and bent to extend away from the face plate; information printed on the tab; the tab forming a plane at an angle of ninety degrees with respect to the face plate; the tab fabricated from a material having a combination of a thickness and a stiffness minimally able to resist a deformation resulting from a force of gravity; a second tab that is integral with the face plate and bent to extend away from the face plate; and the tabs do not infringe on an adjacent space occupied by another high connector density printed circuit board.

### BACKGROUND OF THE INVENTION

1. Field of the Invention

This invention relates generally to high connector density equipment.

2. Description of Related Art

Common language equipment identification (CLEI) is a system and method intended to assist network service providers with planning, buying, identifying, operating and tracking equipment. CLEI systems often include CLEI codes, asset-tracking codes such as CPRs, ECNs and FRCs, bar codes, hardwired assignment codes, frame function codes, a property record catalog, an inventory record catalog and downloadable reports.

A CLEI code is an intelligent, 10-character code that can identify, for example, telecommunications equipment with great precision. Thus, CLEI codes are accepted by telecommunications providers as a de facto industry standard. The primary uses of CLEI include inventory management and provisioning.

There is also typically a one-to-one relationship between a CLEI code and a vendor's product identification numbers and codes. The vendor's product identification information typically defines the manufacturer, part number and manufacturing version of a given part number.

According to the foregoing, there is a need to assist network service providers with planning, buying, identifying, operating and tracking equipment. The implementation of a CLEI system and method is one approach to addressing this need.

The foregoing objects and advantages of the invention are illustrative of those that can be achieved by the various exemplary embodiments and are not intended to be exhaustive or limiting of the possible advantages which can be realized. Thus, these and other objects and advantages of the various exemplary embodiments will be apparent from the description herein or can be learned from practicing the various exemplary embodiments, both as embodied herein or as modified in view of any variation which may be apparent to those skilled in the art. Accordingly, the present invention resides in the novel methods, arrangements, combinations and improvements herein shown and described in various exemplary embodiments.

### SUMMARY OF THE INVENTION

In light of the present need for an optimization of connector density and identification carrier for high connector density front plates, a brief summary of various exemplary embodiments is presented. Some simplifications and omission may be made in the following summary, which is intended to highlight and introduce some aspects of the various exemplary embodiments, but not to limit its scope. Detailed descriptions of a preferred exemplary embodiment adequate to allow those of ordinary skill in the art to make and use the invention concepts will follow in later sections.

When implemented in connection with high connector density equipment, such as telecommunications equipment, CLEI label application is often limited by the lack of sufficient space due to the density of connectors, nomenclature, warning(s) or any combination of the foregoing on the equipment visible surface. Often, there is no surface area on a face plate of the high connector density equipment available to place the CLEI or serial number bar coded label due to connector density and resulting lack of real estate on the faceplate label. The connectors are also referred to herein interchangeably as ports and as connector ports.

In various exemplary embodiments, the problems created by high connector density equipment are solved by simply not including CLEI on the front faceplate of a product. However, such embodiments are believed to be undesirable in applications seeking a CLEI viewable when a unit is in service. It is believed that most applications desire to have the CLEI viewable when the unit is in service.

In various exemplary embodiments, the CLEI is placed on a tag that hangs off of a feature on a face plate of the unit. However, such embodiments require an additional part. Further, such embodiments require the availability of a specific feature in the face plate from which to hang a tag. Still further, the tag hanging off of the face plate in such embodiments will often infringe on the available space for the next slot space for other equipment by hanging below the reserved face plate height in a horizontal arrangement of circuit cards, boards such as printed circuit boards, and so on, or beyond the reserved face plate width in a vertical arrangement of circuit cards, boards and so on. This will be discussed further in connection with FIG. 1.

In order to improve upon the deficiencies in the embodiments described above, various exemplary embodiments include a face plate front surface label that has an integrated tab bent forward, away from the face plate front surface. In various exemplary embodiments, the protrusion comprising the tab constitutes additional usable space for the placement of a CLEI and/or a serial number on a horizontal surface, both top and bottom surfaces of the tab, that does not infringe on any adjoining space reserved for face plates of other circuit cards or boards in an arrangement, while simultaneously not occupying any space on the actual face plate of each given circuit card or board.

According to the foregoing various exemplary embodiments are a high connector density printed circuit board, including one or more of the following: a face plate having a planar surface, the planar surface of the face plate forming a plane; a plurality of connector ports in the face plate; a face plate label applied to the faceplate planar surface; a first tab that is integral with a material of the face plate label and bent to extend away from the plane of the planar surface of the face plate; and information printed on a first surface of the first tab.

In various exemplary embodiments, the first surface of the first tab forms a second plane, and the second plane forms an angle of ninety degrees with respect to the plane of the planar surface of the face plate. In various exemplary embodiments, the first tab is fabricated from a material having a combination of a thickness and a stiffness, the combination causing the first tab to be minimally able to resist a deformation resulting from a force of gravity.

In various exemplary embodiments, written information is imprinted on the face plate label, the written information imprinted on the face plate label having an upright orientation, and the first surface of the first tab is higher in elevation than a second surface of the first tab opposite the first surface of the first tab.

In various exemplary embodiments, written information is imprinted on the face plate label, the written information imprinted on the face plate label having an upright orientation, and the first surface of the first tab is lower in elevation than a second surface of the first tab opposite the first surface of the first tab.

In various exemplary embodiments, the first tab has a second surface opposite the first surface of the first tab and information is written on the second surface of the first tab. In various exemplary embodiments, written information is imprinted on the face plate label, the written information imprinted on the face plate having an upright orientation, and the first tab is located along an edge of the face plate higher in elevation than any other edge of the face plate.

In various exemplary embodiments, written information is imprinted on the face plate label, the written information imprinted on the face plate label having an upright orientation, and the first tab is located along an edge of the face plate lower in elevation than any other edge of the face plate.

Various exemplary embodiments include a second tab that is integral with a material of the face plate label and bent to extend away from the plane of the planar surface of the face plate; and information printed on a first surface of the second tab. In various exemplary embodiments, the information is already printed on the face plate label tab. In various exemplary embodiments, the tab is a carrier supporting the application of a secondary label of similar size as the tab, such as a CLEI label. Accordingly, in various exemplary embodiments, the information is not printed directly on the faceplate (typically a sheet metal part).

In various exemplary embodiments, the face plate includes a face plate label covering the whole surface or a portion of the surface of the face plate. This may be done for esthetics, port naming, card titling, user warning(s), and so on. In various exemplary embodiments, the face plate label has a tab that bends away from the faceplate, for example, at a 90 degree angle. In various exemplary embodiments, the tab is sized to accommodate another small label. In various exemplary embodiments, the label on the tab is used for identification, such as CLEI, a part number, a serial number, or any combination of the foregoing.

In various exemplary embodiments, the second tab is located at an edge of the face plate directly above a one of the plurality of connector ports. In various exemplary embodiments, the information written on the first surface of the second tab identifies the one of the plurality of ports on the face plate.

In various exemplary embodiments, the information printed on the first surface of the first tab is a common language equipment identification. In various exemplary embodiments, the information written on the first surface of the first tab is readable by a human being.

In various exemplary embodiments, the first tab does not infringe on an adjacent space occupied by another high connector density printed circuit board. In various exemplary embodiments, each of the plurality of connector ports are selected from the list consisting of an input connector, an output connector, a coaxial cable, an Ethernet port, a modem connection, an electrical connection, an optical connection, and a telephone connector. Various exemplary embodiments include at least one extractor for ejecting the printed circuit board from a slot.

Various exemplary embodiments are a high connector density printed circuit board, including one or more of the following: a face plate having a planar surface, the planar surface of the face plate forming a plane; a plurality of connector ports in the face plate; a tab that extends away from the plane of the planar surface of the face plate; a hinge connecting the tab to the face plate such that the tab rotates around an axis formed by the hinge; and information printed on a surface of the tab, the information being readable by a human being, wherein the tab is fabricated from a material having a combination of a thickness and a stiffness, the combination being such that the hinge is minimally able to resist a rotation resulting from a force of gravity, and the tab does not infringe on an adjacent space occupied by another high connector density printed circuit board.

Various exemplary embodiments are a high connector density device, including one or more of the following: a first slot for receiving a first high connector density printed circuit board; a second slot for receiving a second high connector density printed circuit board; a first high connector density printed circuit board inserted in the first slot; and a second high connector density printed circuit board inserted in the second slot.

### BRIEF DESCRIPTION OF THE DRAWINGS

In order to better understand various exemplary embodiments, reference is made to the accompanying drawings, wherein:

FIG. 1 is a fragmented front view of an exemplary embodiment of high connector density equipment;

FIG. 2 is a perspective view of a first exemplary embodiment of a high connector density printed circuit board;

FIG. 3 is a perspective view of a second exemplary embodiment of a high connector density printed circuit board;

FIG. 4 is a perspective view of a third exemplary embodiment of a high connector density printed circuit board; and

FIG. 5 is a perspective view of a fourth exemplary embodiment of a high connector density printed circuit board.

### DETAILED DESCRIPTION OF THE PREFERRED EMBODIMENTS OF THE INVENTION

Referring now to the drawings, in which like numerals refer to like components or steps, there are disclosed broad aspects of various exemplary embodiments.

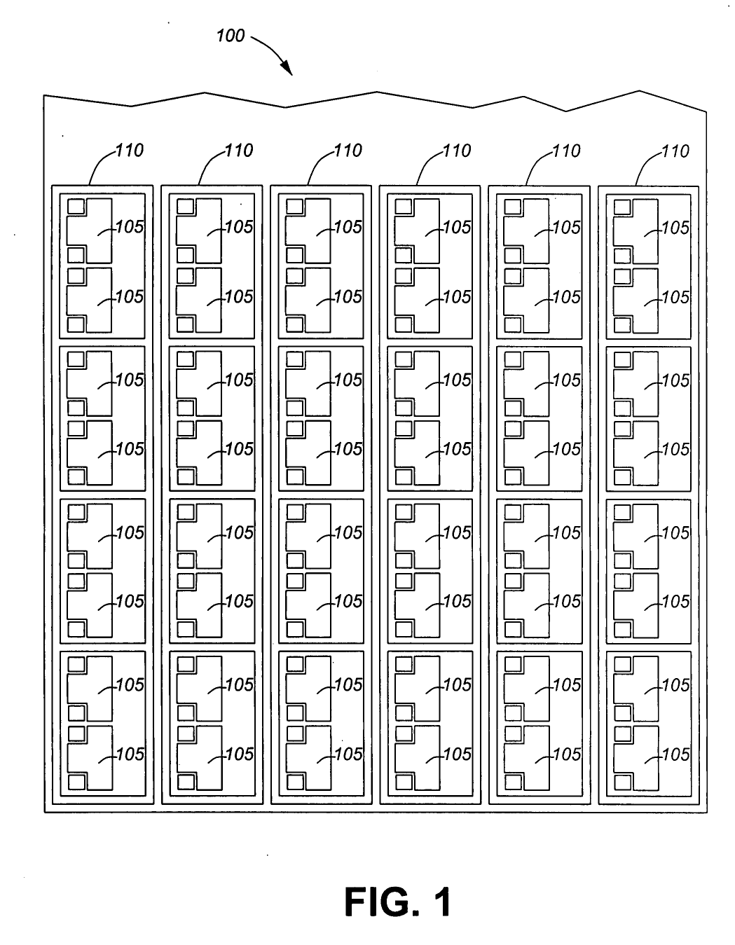

FIG. 1 is a fragmented front view of an exemplary embodiment of high connector density equipment 100. High connector density equipment 100 includes six circuit cards 110. The circuit cards 110 are also interchangeably referred to herein as boards, printed circuit boards, circuit boards, cards or blades. As depicted, each circuit card 110 includes eight connector ports 105.

It should be understood that the proportions and relative orientations of the connector ports 105 on the face plate of each circuit card 110 as depicted in FIG. 1 are not intended to be to scale. Rather, the high connector density equipment 100 depicted in FIG. 1 shows a congested front panel or face plate application typical of that found in many applications such as telecommunications equipment.

Because of the crowded nature of such applications, it should be apparent that the utilization of real estate on the front panel of each circuit card 110 is important. Likewise, it should be apparent that it is desirable to optimize the utilization of the space or real estate on the front panel of each circuit card 110 in congested applications such as those found in telecommunications equipment.

As depicted in FIG. 1, the circuit cards 110 are installed in the high connector density equipment 100 in a vertical orientation. In various other embodiments, the circuit cards 110 are rotated clockwise 90 degrees resulting in a horizontal orientation of the circuit cards 110 in the high connector density equipment 100.

It should also be apparent that the front panel area of each circuit card 110 restricts the number of connector ports 105 physically capable of fitting within the space of the front panel on each circuit card 110. In various exemplary embodiments, the number of available connector ports 105 for the circuit card 110 correlates to a number of potential customers that can be serviced with the equipment 100. Correspondingly, the number of connector ports 105 that can fit in the space on the front panel of each circuit card 110 can be directly related to revenues obtained by the entity manufacturing circuit cards 110 and the entity operating systems that incorporate circuit cards 110.

In various industries, the relative height and width of circuit cards 110 is determined according to an industry-wide convention. However, it should be apparent that, the concepts of the invention described herein are applicable regardless of the specific details regarding the height and width of the circuit card 110.

It should also be apparent that the slots space provided in high connector density equipment 100 for circuit cards 110 corresponds, in various exemplary embodiments, to the slots provided in a typical personal computer (PC) for PC cards that enable various functions of the personal computer. Turning again to applications in the telecommunications (telecom) industry, a printed circuit board (PCB) is the name of a common card used in telecom. Thus, in various exemplary embodiments, the circuit cards 110 are PCB cards.

It should be similarly apparent that, in various exemplary embodiments, the connector ports 105 correspond to any known or later developed convention for connector ports. For example, connector ports 105 are any known form of input and/or output connectors in any application utilizing connector ports for inputs and/or outputs. Accordingly, in various exemplary embodiments, the connector ports 105 are coaxial cable connectors. In various exemplary embodiments, the connector ports 105 are Ethernet ports. In various exemplary embodiments, the connector ports 105 are Modem connections. In various exemplary embodiments, the connector ports 105 are electrical connections. In various exemplary embodiments, the connector ports 105 are optical connections such as SFP ports. In various exemplary embodiments in telecom, the connector ports 105 are telephone connectors such as RJ45 connectors or other types of RJ connectors utilized in telecom applications, including, but not limited to, RJ21 connector ports. In various exemplary embodiments, the connector ports 105 are d-subs, alarms, power, and so on, including any currently known or later developed port implemented in such equipment.

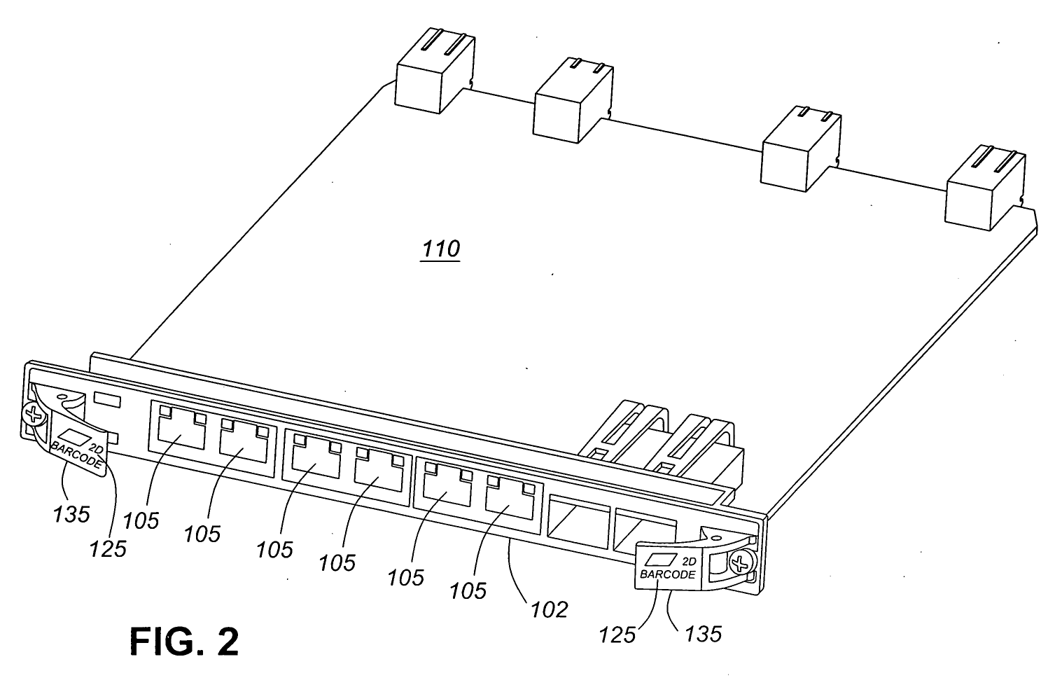

FIG. 2 is a perspective view of a first exemplary embodiment of a high connector density printed circuit board 110. High connector density printed circuit board 110 includes a face plate 102 having a plurality of connector ports 105. As used herein, the face plate 102 is alternatively also referred to as a front panel 102 or a front plate 102. In various exemplary embodiments, the face plate 102 requires space that is not utilized for a connector port 105 in order to support printed information directly on the face plate 102 or alternatively on a face plate label, adhered to the face plate 102 front surface, with printed information such as a card title, a card identification (ID) label, an so on. Accordingly, all references herein to printing information directly on the face plate 102, or directly on the tab 120, should be understood to include printing information on a label adhering to the face plate 102 and the tab 120.

In various exemplary embodiments, the information printed directly on the face plate 102 is general information about the card 110 understandable by a typical user of the card 110. Further, the high connector density printed circuit board 110 includes ejectors 135. The ejectors 135 are also sometimes referred to as extractors.

As depicted in the exemplary high connector density printed circuit board 110, the ejectors 135 protrude laterally into space above the face plate 102. As depicted in exemplary high connector density printed circuit board 110, the protrusion of the ejectors 135 is necessary in order to provide a surface on a face of the ejectors 135 where an identification label such as barcode 125 or alpha numerical information, or CLEI is printed. However, embodiments such as the high connector density printed circuit board 110 are believed to be undesirable because the protrusion of the ejectors 135 necessary to provide an adequate amount of space for the identification label 125 is such that the accessibility of the connector ports 105 on the surface of the face plate 102 is inhibited.

In various exemplary embodiments, additional surface is required on the face plate 102 in order to provide safety warnings or illuminated indicators of various functions such as LEDs. Accordingly, it should be apparent that it is desirable to optimize the space available on the face plate 102 for connector ports 105.

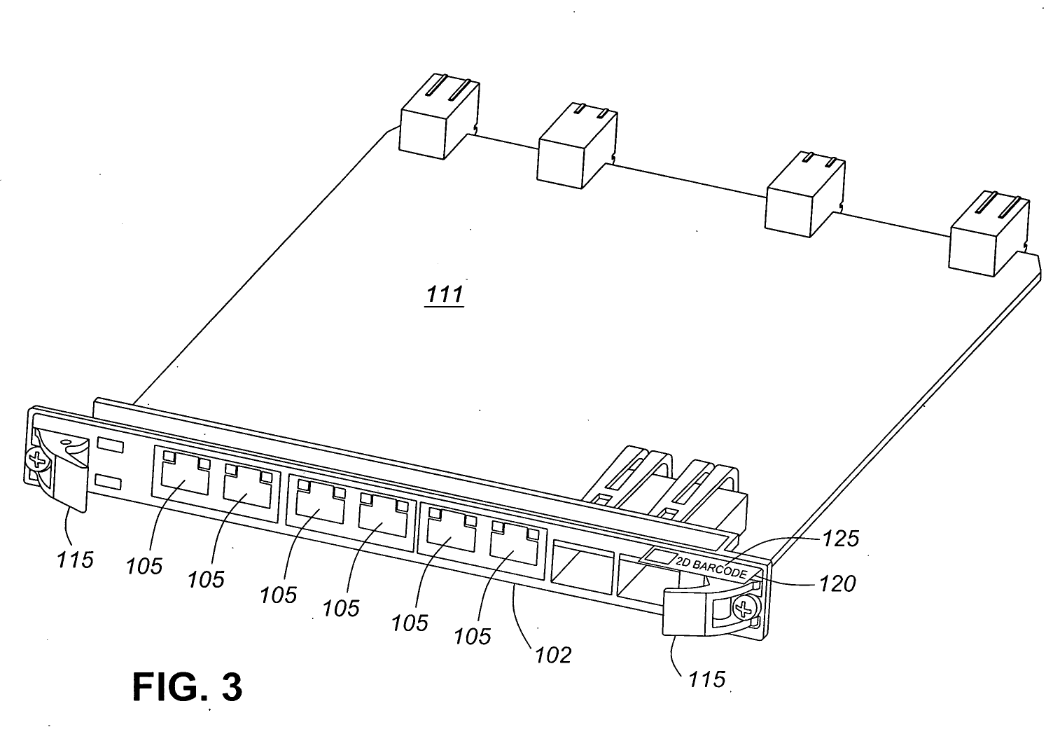

FIG. 3 is a perspective view of a second exemplary embodiment of a high connector density printed circuit board 111. Many consumers or purchasers of circuit cards prefer a circuit card that has an externally visible part number, an externally visible serial number label, and an externally visible CLEI label. In various exemplary embodiments, the surface area on the face plate 102 to provide the desired labels can amount to 1.0 square inches. Thus, on a narrow circuit card such as a circuit card one half of an inch in height, as much as two inches of linear space on the face plate 102 of the circuit card are not available for ports 105 because it must be used for visible text.

Accordingly, the high connector density printed circuit board 111 includes ejectors 115 that do not have any requirement for visible written text printed thereon. Thus, ejectors 115 do not protrude laterally into a surface of the face plate 102 in a magnitude as large as the protrusion of ejectors 135. Rather, the high connector density printed circuit board 111 includes tab 120. In various exemplary embodiments, tab 120 is bent away from a faceplate label (not shown) and the 2D barcode 125 is printed on a top surface or a bottom surface, or both, of the tab 120. In various exemplary embodiments, the 2D barcode 125 is printed on a small label that is applied on the tab top surface or bottom surface, or both, of the tab 120.

As depicted, the 2D barcode 125 is intended merely as an example of any kind of printed information. Thus, in various exemplary embodiments the 2D barcode 125 is another type of barcode, both known and later developed. Likewise, in various exemplary embodiments, the 2D barcode 125 is any type of printed identification other than a barcode, both known and later developed. Similarly, in various exemplary embodiments, the 2D barcode 125 is any form of printed information.

In various exemplary embodiments, the dimensions of the tab 120 are designed to conform with the standard CLEI format. By virtue of the placement of the tab 120, in various exemplary embodiments, the front panel 102 of high connector density printed circuit board 111 has more space available for connector ports 105 than the front panel 102 of high connector density printed circuit board 110.

As depicted in connection with high connector density printed circuit board 111, the tab 120 protrudes away from a surface of the front panel 102. In various exemplary embodiments, the size and dimensions of the tab 120 are designed to accommodate the text of the part identification label that is to appear on the tab 120 such as the 2D barcode 125.

In various exemplary embodiments, the protrusion to form the tab 120 is created by bending a portion of the front panel label 102 specifically created for the purpose of forming the tab 120. Accordingly, in various exemplary embodiments, the tab 120 is fabricated from a material of sufficient thickness to maintain the necessary rigidity to bend the tab 120 ninety degrees away from a plane of the front panel 102.

It should be apparent, that, in various exemplary embodiments, the tab 120 is formed at an angle greater than or less than ninety degrees from the plane of the front panel 102. Similarly, in various exemplary embodiments, the tab 120 is fabricated from a material having a stiffness adequate to remain bent away from the plane of the front panel 102 as depicted. In various exemplary embodiments, the stiffness of the material forming the tab 120 and the thickness of the tab 120 are only what is minimally necessary to support the tab 120 against the force of gravity.

In various exemplary embodiments, a top surface of the tab 120 does not contain any adhesive. In various exemplary embodiments the 2D barcode 125 appears on the top surface of the tab 120. In various exemplary embodiments, a bottom surface of the tab 120, not visible in the perspective of FIG. 3, also includes an identification label.

In various exemplary embodiments, the identification label on the bottom surface of the tab 120 is a secondary part identification label. Although not necessarily preferable for many applications, it should also be apparent that, in various exemplary embodiments, the bottom surface of the tab 120 is used for a primary part identification label. Similarly, it should be apparent that, in various exemplary embodiments, the primary part identification label is placed on both the top and the bottom surface of the tab 120.

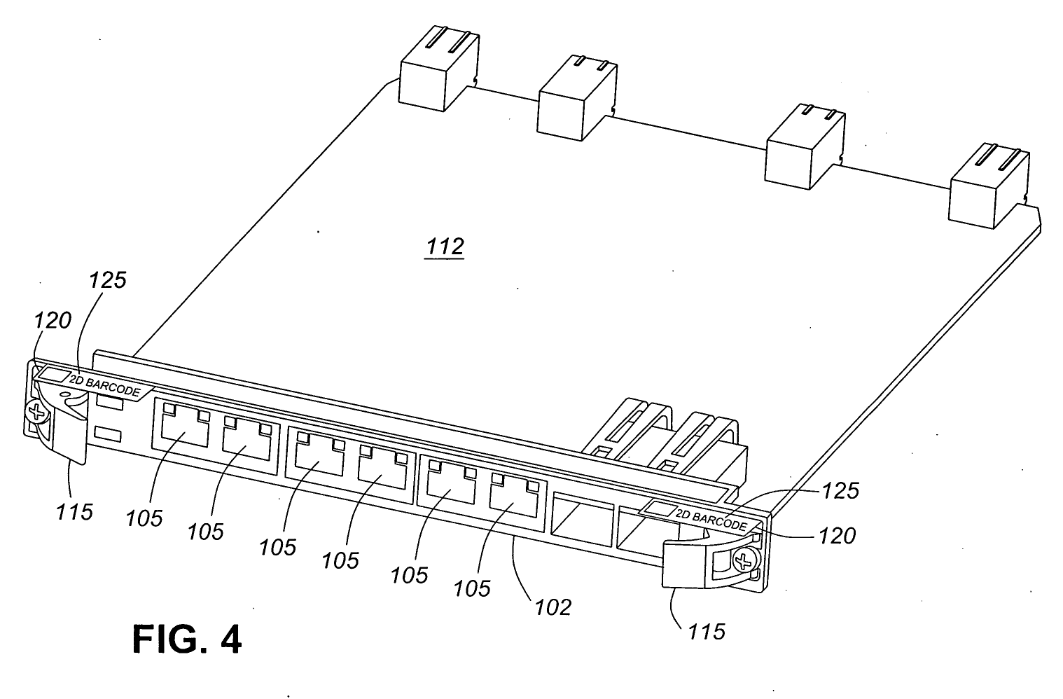

FIG. 4 is a perspective view of a third exemplary embodiment of a high connector density printed circuit board 112. The high connector density printed circuit board 112 includes a plurality of tabs 120. As depicted, the high connector density printed circuit board 112 includes a first tab 120 at an upper left edge of the front panel 102 and a second tab 120 at an upper right edge of the front panel 102.

It should be apparent that, in various exemplary embodiments, any number of tabs 120 greater than one are incorporated. Similarly, it should be apparent that, in various exemplary embodiments, the location of the tabs 120 can be at any point laterally on the face plate 102. Likewise, it should be apparent that, in various exemplary embodiments, one or more of the tabs 120 are located at a bottom edge of the face plate 102.

Because the tabs 120 extend horizontally away from the plane of a surface of the front plate 102, it should be apparent that the tabs 120 do not infringe on the space necessary to accomplish connections through the connector ports 105 even if the tab 120 is located directly in line with one or more of the ports 105 along the face plate 102. It should be apparent that, the benefit of including a plurality of tabs 120 include, but are not limited to, the ability to label the high connector density printed circuit board 112 with a greater number of identification labels, a greater variance of data of identification labels, labels for the connector ports 105, safety warnings, and so on.

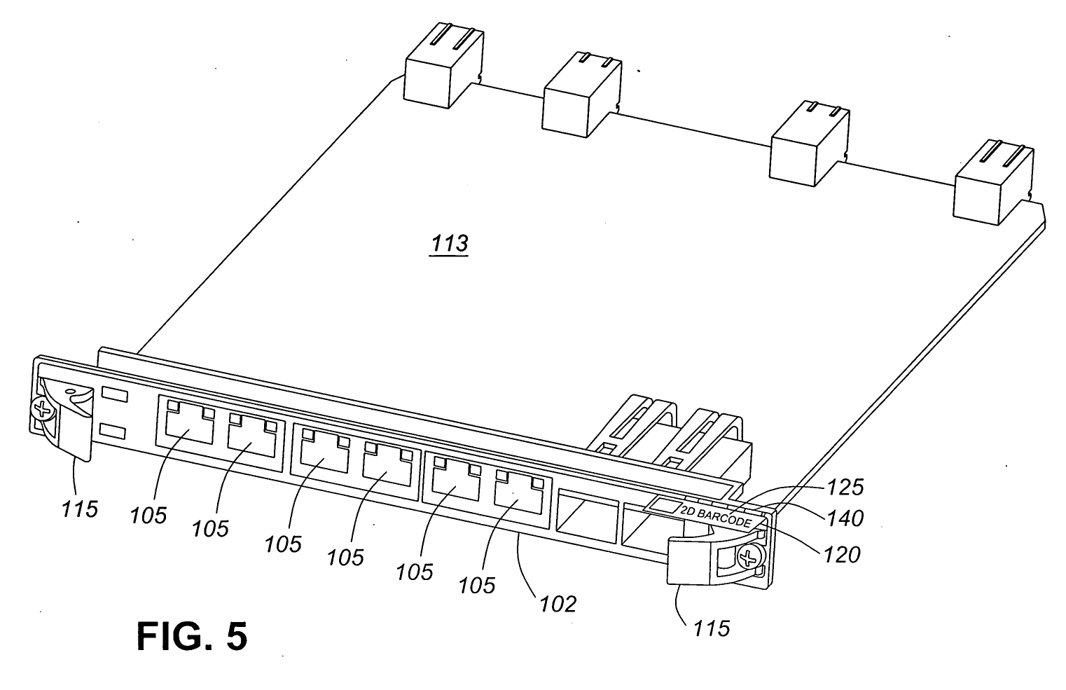

FIG. 5 is a perspective view of a fourth exemplary embodiment of a high connector density printed circuit board 113. The high connector density printed circuit board 113 includes a tab 120 that is connected to the face plate 102 by a hinge 140. As with the description of the tabs 120 in connection with the other figures herein, the tab 120 in high connector density printed circuit board 113 has sufficient tension in the hinge 140 to remain in a fixed position in opposition to the force of gravity.

However, in various exemplary embodiments, the tab 120 can be rotated to a different angle with respect to the plane of the surface of the face plate 102. This functionality obtained by incorporating the hinge 140 enables the user of the high connector density printed circuit board 113 to read the 2D barcode 125 on the tab 120 from a variety of physical orientations in space by rotating the tab 120 through hinge 140.

According to the foregoing, the manufacturers of equipment containing CLEI labels are able to place the CLEI labels in an accessible location that is readable to a human viewer without impacting the available density of connector ports 105 on the face plate 102. Accordingly, various exemplary embodiments increase the density of connector ports 105 without impacting the availability of part identification labeling for the various circuit cards. Thus, a variety of customer and industry requirements are able to be met by various exemplary embodiments with a higher density of communication ports 105 than previously available.

It should be apparent that cards having a higher density of communication ports 105 are advantageous for the user of such cards. Accordingly, it is believed to be of significant utility to utilize the various exemplary embodiments described herein.

As described herein, telecommunications suppliers, for example, will find an advantage in incorporating the subject matter described herein in order to overcome a problem related to the lack of usable area to support proper industry standard part identification labeling requirements. This is accomplished because various exemplary embodiments increase the usable area on the surface of the face plate 102 for connector ports 105 and, correspondingly, directly result in an increased revenue for such suppliers.

Although the various exemplary embodiments have been described in detail with particular reference to certain exemplary aspects thereof, it should be understood that the invention is capable of other different embodiments, and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only, and do not in any way limit the invention, which is defined only by the claims.

What is claimed is:

1. A high connector density printed circuit board, comprising:
a face plate having a planar surface, the planar surface of the face plate forming a plane;
a plurality of connector ports in the face plate;
a face plate label applied to the faceplate planar surface;
a first tab that is integral with a material of the face plate label and bent to extend away from the plane of the planar surface of the face plate; and
information printed on a first surface of the first tab.

2. The high connector density printed circuit board, according to claim 1, wherein the first surface of the first tab forms a second plane, and the second plane forms an angle of ninety degrees with respect to the plane of the planar surface of the face plate.

3. The high connector density printed circuit board, according to claim 1, wherein the first tab is fabricated from a material having a combination of a thickness and a stiffness, the combination causing the first tab to be minimally able to resist a deformation resulting from a force of gravity.

4. The high connector density printed circuit board, according to claim 1, wherein
written information is imprinted on the face plate label, the written information imprinted on the face plate label having an upright orientation, and
the first surface of the first tab is higher in elevation than a second surface of the first tab opposite the first surface of the first tab.

5. The high connector density printed circuit board, according to claim 1, wherein
written information is imprinted on the face plate label, the written information imprinted on the face plate label having an upright orientation, and
the first surface of the first tab is lower in elevation than a second surface of the first tab opposite the first surface of the first tab.

6. The high connector density printed circuit board, according to claim 1, wherein the first tab has a second surface opposite the first surface of the first tab and information is written on the second surface of the first tab.

7. The high connector density printed circuit board, according to claim 1, wherein
written information is imprinted on the face plate label, the written information imprinted on the face plate label having an upright orientation, and
the first tab is located along an edge of the face plate higher in elevation than any other edge of the face plate.

8. The high connector density printed circuit board, according to claim 1, wherein
written information is imprinted on the face plate label, the written information imprinted on the face plate label having an upright orientation, and
the first tab is located along an edge of the face plate lower in elevation than any other edge of the face plate.

9. The high connector density printed circuit board, according to claim 1, further comprising:
a second tab that is integral with a material of the face plate label and bent to extend away from the plane of the planar surface of the face plate; and
information printed on a first surface of the second tab.

10. The high connector density printed circuit board, according to claim 9, wherein the second tab is located at an edge of the face plate directly above a one of the plurality of connector ports.

11. The high connector density printed circuit board, according to claim 10, wherein the information written on the first surface of the second tab identifies the one of the plurality of ports on the face plate.

12. The high connector density printed circuit board, according to claim 1, wherein the information printed on the first surface of the first tab is a common language equipment identification.

13. The high connector density printed circuit board, according to claim 1, wherein the information written on the first surface of the first tab is readable by a human being.

14. The high connector density printed circuit board, according to claim 1, wherein the first tab does not infringe on an adjacent space occupied by another high connector density printed circuit board.

15. The high connector density printed circuit board, according to claim 1, wherein each of the plurality of connector ports are selected from the list consisting of an input connector, an output connector, a coaxial cable, an Ethernet port, a modem connection, an electrical connection, an optical connection, and a telephone connector.

16. The high connector density printed circuit board, according to claim 1, further comprising at least one extractor for ejecting the printed circuit board from a slot.

17. A high connector density printed circuit board, comprising:
a face plate having a planar surface, the planar surface of the face plate forming a plane;
a plurality of connector ports in the face plate;
a tab that extends away from the plane of the planar surface of the face plate;
a hinge connecting the tab to the face plate such that the tab rotates around an axis formed by the hinge; and
information printed on a surface of the tab, the information being readable by a human being, wherein
the tab is fabricated from a material having a combination of a thickness and a stiffness, the combination being such that the hinge is minimally able to resist a rotation resulting from a force of gravity, and
the tab does not infringe on an adjacent space occupied by another high connector density printed circuit board.

18. A high connector density device, comprising:
a first slot for receiving a first high connector density printed circuit board;
a second slot for receiving a second high connector density printed circuit board;
a first high connector density printed circuit board inserted in the first slot; and
a second high connector density printed circuit board inserted in the second slot,
the first high connector density printed circuit board comprising:
a face plate having a planar surface, the planar surface of the face plate forming a plane;
a plurality of connector ports in the face plate;
a face plate label applied to the faceplate planar surface;
a tab that is integral with a material of the face plate label and bent to extend away from the plane of the planar surface of the face plate; and
information printed on a surface of the tab.

19. The high connector density device, according to claim 18, wherein the tab does not infringe on an adjacent space occupied by the second high connector density printed circuit board.

20. The high connector density device, according to claim 18, wherein the tab is fabricated from a material having a combination of a thickness and a stiffness, the combination causing the tab to be minimally able to resist a deformation resulting from a force of gravity.
